(19) United States
(12) Patent Application Publication
(10) Pub. No.: US 2026/0333820 A1
(43) Pub. Date: Oct. 22, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yu-Jhen Jiang, Hsinchu (TW); Yun-Ting Chiang, Hsinchu County (TW); Chun-Cheng Chou, Taichung City (TW); Yu-Shih Wang, Tainan City (TW); Chun-Neng Lin, Hsin-chu (TW)

(73) Assignee: Taiwan Semiconductor Manufacturing Company, Ltd., Hsinchu (TW)

(21) Appl. No.: 19/184,342

(22) Filed: Apr. 21, 2025

(51) Int. Cl. H10D 64/23; H10D 84/01; H10D 84/83

(52) U.S. Cl. CPC H10D 64/258; H10D 84/0149; H10D 84/832

(57) ABSTRACT

A method includes: forming a trench in a dielectric layer above a source/drain terminal of a semiconductor structure; forming a recess in a top surface of a source/drain terminal that extends below the dielectric layer; forming a source/drain contact in the trench and recess; wherein the source/drain contact has a first length between ends of the trench; and wherein the source/drain contact has a second length underneath the dielectric layer; wherein the second length is greater in magnitude than the first length.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method 100 of semiconductor fabrication including fabrication of multi-gate devices, in accordance with some embodiments.

FIGS. 2-3, 4A-4C, 5, 6A-6B, and 7-23, are schematic diagrams of a semiconductor structure at various stages of fabrication, in accordance with some embodiments.

FIG. 24 is a schematic diagram illustrating an example contact loop in a transistor device, in accordance with some embodiments.

FIG. 25 is a flow diagram depicting an example method for forming a source/drain contact (e.g., VD plug) with lower resistance, according to various aspects of the present disclosure.

FIGS. 26-29 are schematic diagrams of a semiconductor structure at various stages of fabrication, in accordance with some embodiments.

FIG. 30 depicts a cross-sectional view of an example semiconductor structure, in accordance with some embodiments.

FIG. 31 depicts a schematic cross-sectional view of an example semiconductor structure, in accordance with some embodiments.

FIG. 32 depicts a perspective view of an example semiconductor structure, in accordance with some embodiments.

FIG. 33 depicts a schematic cross-sectional view of an example semiconductor structure, in accordance with some embodiments.

FIG. 34 depicts a schematic cross-sectional view of the section of the example semiconductor structure of FIG. 33, in accordance with some embodiments.

FIG. 35 depicts a cross-sectional view of an example semiconductor structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

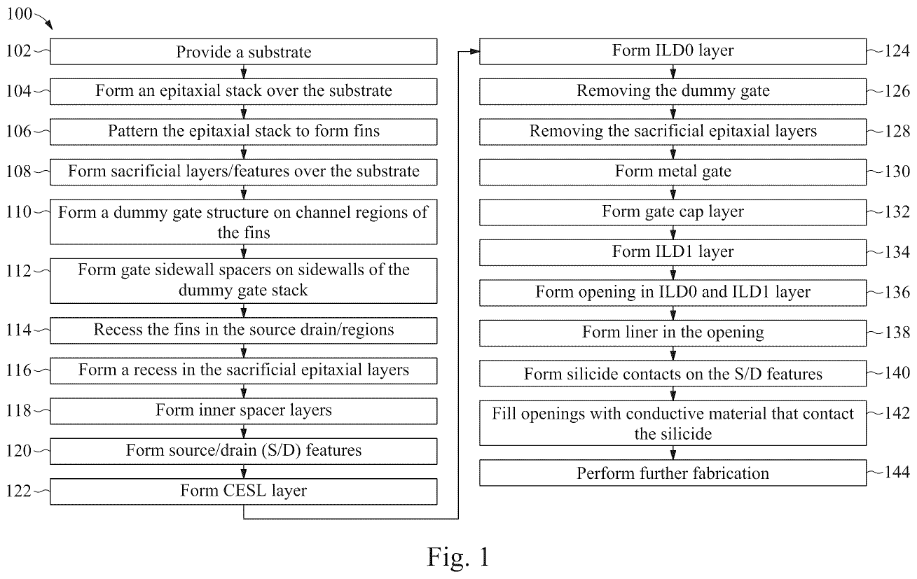

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

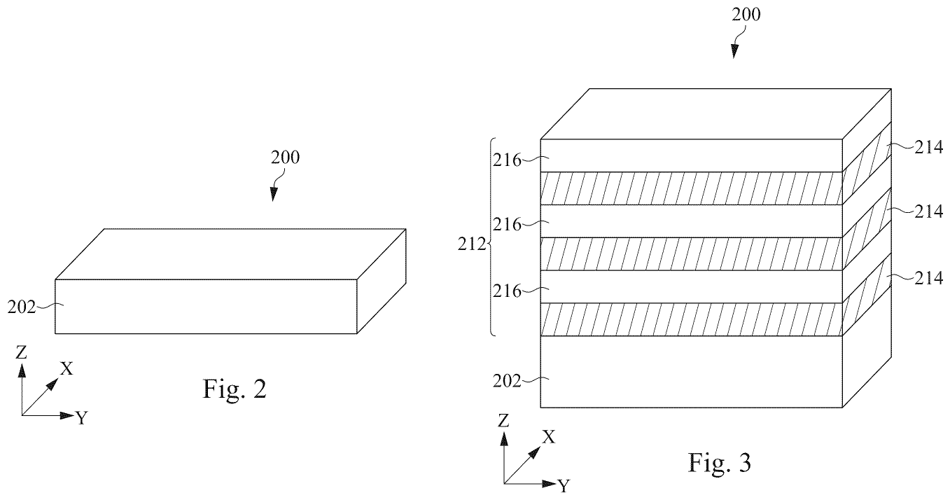

FIG. 1 is described in conjunction with FIGS. 2-3, 4A-4C, 5, 6A-6B, and 7-23, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2-3, 4A-4C, 5, 6A-6B, and 7-23, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a semiconductor device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 then includes forming an epitaxial stack over the substrate that includes a plurality of epitaxial layers. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 2 and 10, such as 3, 4 or 5.

In some embodiments, the sacrificial epitaxial layer 214 has a thickness ranging from about 4 nm (nanometers) to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25~55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

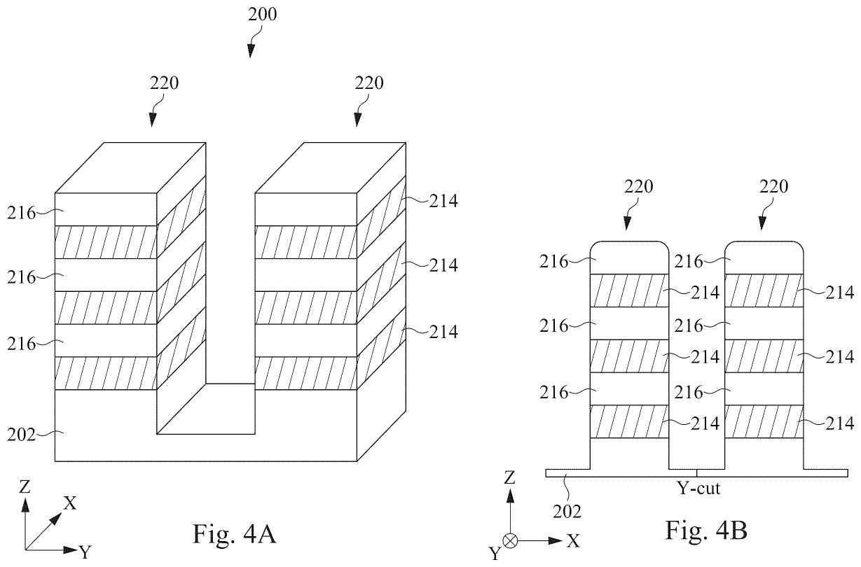

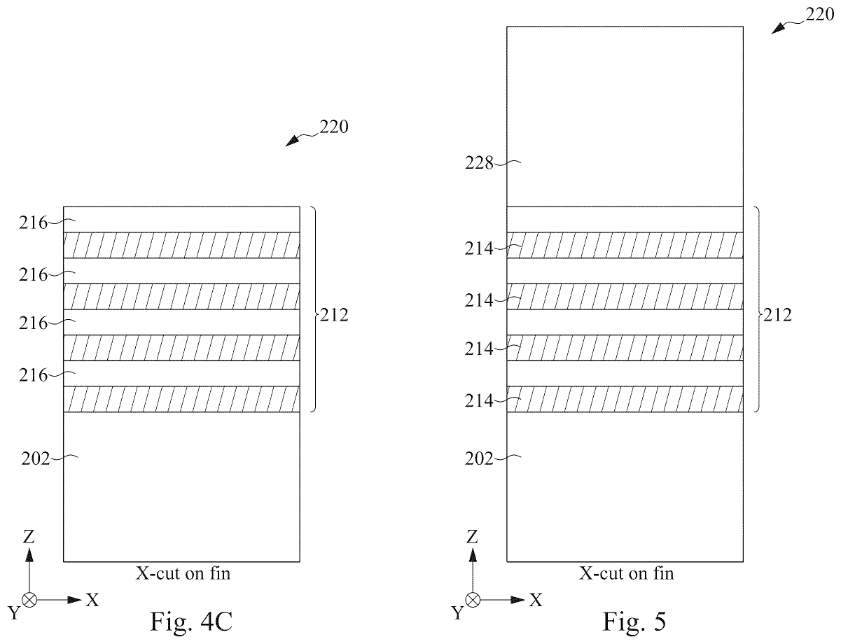

At block 106, the example method 100 includes patterning the epitaxial stack to form semiconductor fins (also referred to as fins). Referring to the example of FIGS. 4A, 4B, and 4C, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming one or more sacrificial layers/features over the substrate. Referring to the example of FIG. 5, in an embodiment of block 108, a sacrificial gate dielectric layer (not shown) is blanket deposited over a stop layer 222, which is formed over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

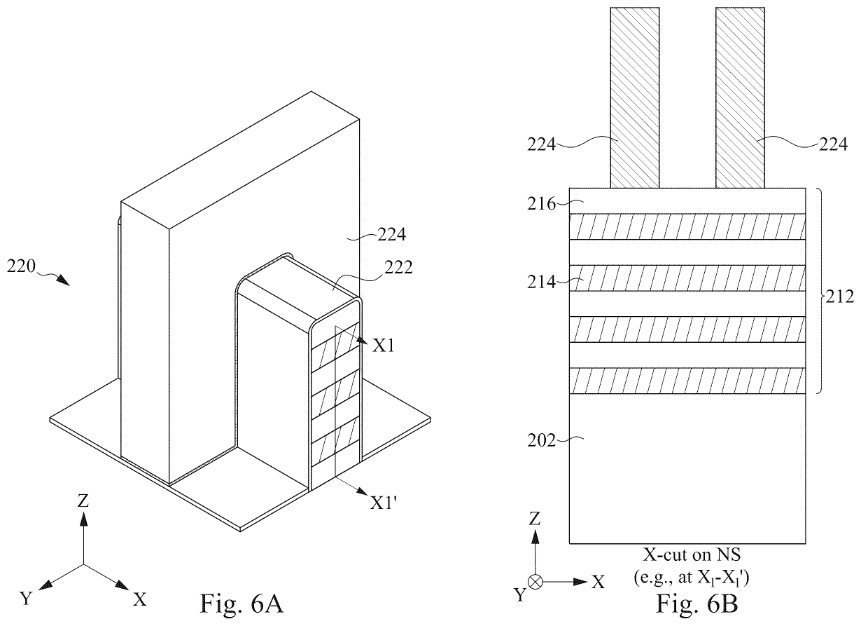

At block 110, the example method 100 includes patterning the one or more sacrificial layers/features to form a dummy gate structure on channel regions of the fins. Referring to the example of FIGS. 6A and 6B, in an embodiment of block 110, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 132 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

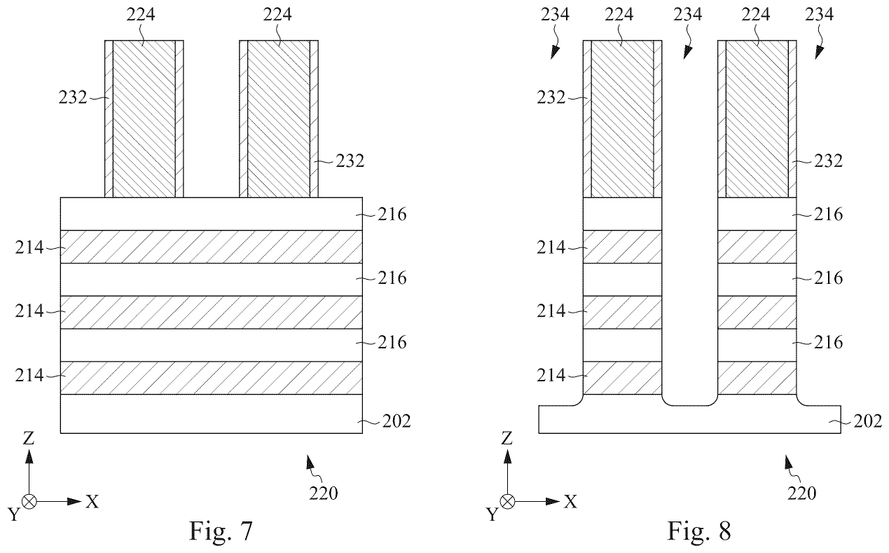

At block 112, the example method 100 includes forming gate sidewall spacers on sidewalls of the sacrificial gate structure. Referring to the example of FIG. 7, in an embodiment of block 112, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 114, the example method includes recessing the fins in the source drain/regions. Referring to the example of FIG. 8, in an embodiment of block 116, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF4, SF6, CH2F2, CHF3, and/or C2F6), other suitable gases, or combinations thereof.

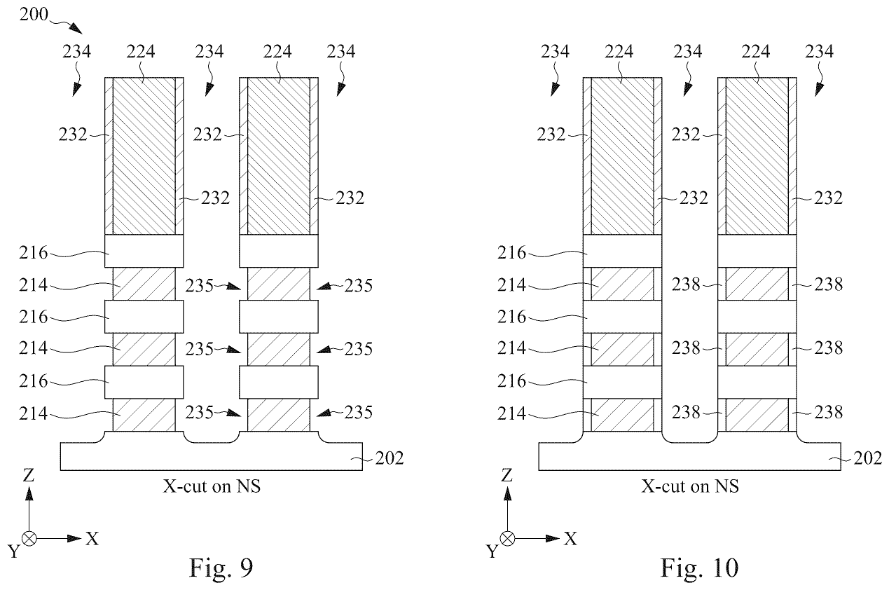

At block 116, the example method 100 includes forming a recess in the sacrificial epitaxial layers (e.g., SiGe) of the epitaxial stack. Referring to the example of FIG. 9, in an embodiment of block 116, the sacrificial epitaxial layers 214 have been etched back forming sacrificial epitaxial layer recesses 235 bounded on the top and bottom by channel epitaxial layers 216 and laterally by the recessed sacrificial epitaxial layers 214. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 118 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

At block 118, the example method 100 Includes forming an inner spacer layer in the sacrificial epitaxial layer recesses. Forming the inner spacer layer may include depositing inner spacer material of a first material type in the sacrificial epitaxial layer recesses, and trimming the inner spacer layers (e.g., via etching operations). Referring to the example of FIG. 10, in an embodiment of block 118, inner spacer layers 238 are formed in the sacrificial epitaxial layer recesses 235. The inner spacer layers 238 may be formed from may be formed from silicon oxides, silicon nitrides, silicon carbides, silicon carbide nitride, silicon oxide carbide, silicon carbide oxynitride, and/or other suitable dielectric materials. In some embodiments, the inner spacer layer 238 is deposited as a conformal layer. The inner spacer layers 238 can be formed by ALD or any other suitable method. In various embodiments, the inner spacer layers 238 are formed from the same material as the gate sidewall spacers 232. In various embodiments, the gate sidewall spacers 232 and the inner spacer layers 238 are formed from SiOCN.

At block 120, the example method 100 includes forming source/drain (S/D) features. Forming the S/D features may involve depositing pure silicon in the recess 234 in the source drain/regions. In various embodiments, recessing the fins in the S/D regions may involve over etching the fins in the S/D regions wherein some of the substrate 202 below the height level of the bottom sacrificial epitaxial layer 214 is removed to prevent SiGe residue. Pure Si may be deposited in the recess 234 to raise the height of the substrate 202 below the recess 234 to the height level of the bottom sacrificial epitaxial layer 214.

Forming the S/D features may also involve depositing AlOx over the NMOS S/D regions and the PMOS S/D regions, patterning the PMOS S/D regions to remove the AlOx over the PMOS S/D regions, and depositing PMOS material for forming epitaxial S/D features in the PMOS S/D regions. Following forming the epitaxial S/D features in the PMOS S/D regions, forming the S/D features may involve depositing AlOx over the PMOS S/D regions, patterning the NMOS S/D regions to remove the AlOx over the NMOS S/D regions, and depositing NMOS material for forming epitaxial S/D features in the NMOS S/D regions.

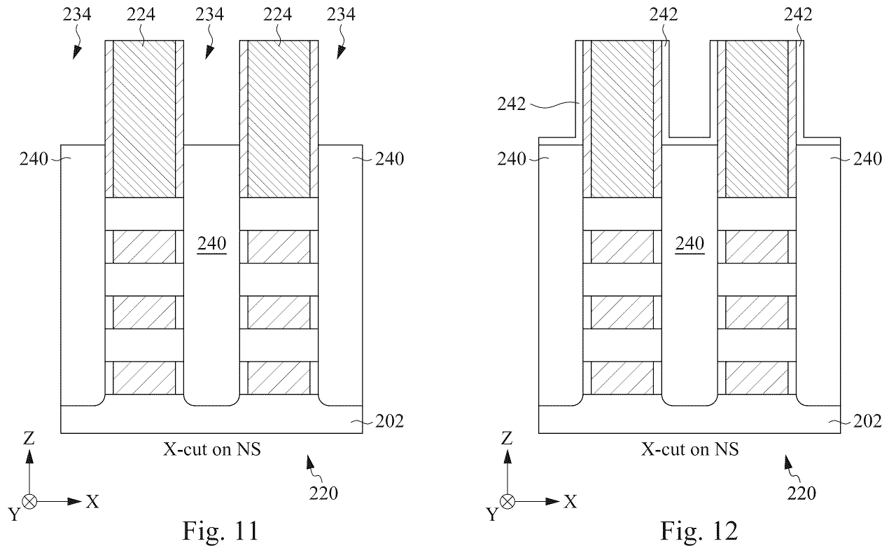

Referring to the example of FIG. 11, in an embodiment of block 122, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the inner spacer layers 238.

At block 122, the example method 100 includes forming a CESL layer. Referring to the example of FIG. 12, in an embodiment of block 124, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

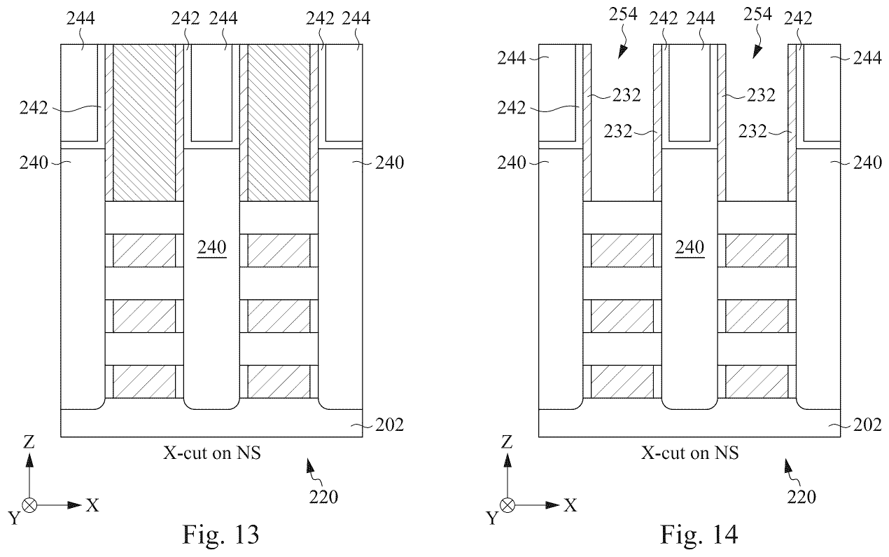

At block 124, the example method 100 includes forming an ILD layer. Referring to the example of FIG. 13, in an embodiment of block 124, a first interlayer dielectric (ILD0) layer 244 is formed over the CESL layer 242. The ILD0 layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD0 layer 244 may be formed by PECVD, flowable CVD (FCVD), or other suitable methods. In some embodiments, forming the ILD0 layer 244 further includes performing a CMP process to planarize a top surface of the device 200, such that the top surfaces of the sacrificial gate structure 224 are exposed.

At block 126, the example method 100 includes removing the dummy gate stack to form a gate trench. Referring to the example of FIG. 14, in an embodiment of block 126, the sacrificial gate structure 224 has been removed to form a gate trench 254. The gate trench 254 exposes the fin 220 in the channel region(s). The ILD0 layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD0 layer 244 is an oxide, a wet etchant such as a TMAH solution can be used to selectively remove the sacrificial gate electrode layer. The sacrificial gate dielectric layer is thereafter removed using plasma dry etching and/or wet etching.

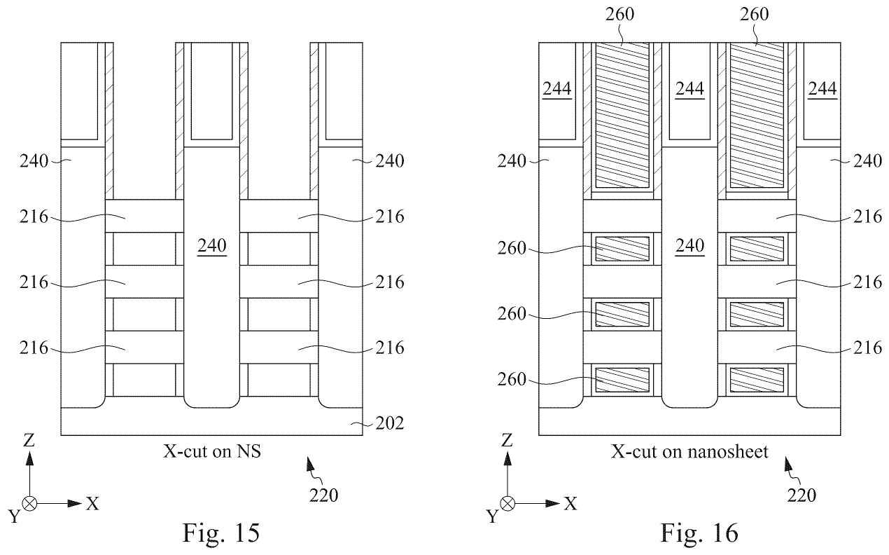

At block 128, the example method 100 includes removing the sacrificial epitaxial layers to form nanosheets. Referring to the example of FIG. 15, in an embodiment of block 128, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

At block 130, the example method 100 includes forming high-K metal gate structures. Referring to the example of FIG. 16, in an embodiment of block 130, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

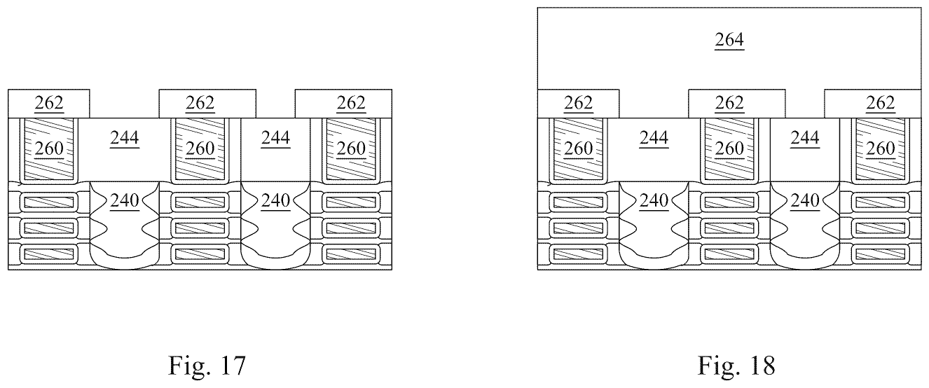

At block 132, the example method 100 includes forming a dielectric gate cap layer over the metal gate structures. The dielectric gate cap layer may be formed by a selective deposition of a dielectric, such as SiN over the metal gate structures, but not the surrounding ILD0 layer. The dielectric gate cap layer can function to protect the gate structure during subsequent metal drain (MD) formation. The dielectric gate cap layer may be formed using a type of area-selective deposition process wherein deposition occurs at selected areas. Referring to the example of FIG. 17, in an embodiment of block 132, the example semiconductor structure includes a dielectric layer 262 deposited over the gate structure 260. The dielectric layer 262, however, is not formed over the ILD0 layer 244.

At block 134, the example method 100 includes forming a second ILD layer (ILD1 layer) over the ILD0 layer and the dielectric gate cap layer. Referring to the example of FIG. 18, in an embodiment of block 134, the example semiconductor structure includes an ILD1 layer 264 formed over the ILD0 layer 244 and the dielectric layer 262. The ILD1 layer 264 may include or be a material such as silicon nitride (SiN), although other suitable materials, such as silicon oxide (SiO2), aluminum oxide (AIO), silicon oxycarbide (SiOC), silicon carbon (SiC), zirconium nitride (ZrN), zirconium oxide (ZrO), combinations of these, or the like, may also be utilized. The ILD1 layer 264 may be deposited using a deposition process such as plasma enhanced atomic layer deposition (PEALD), thermal atomic layer deposition (thermal ALD), plasma enhanced chemical vapor deposition (PECVD), or others. Any suitable deposition process and process conditions may be utilized.

At block 136, the example method 100 includes forming an opening in the ILD0 layer and the ILD1 layer that expose the underlying source/drain features. Forming an opening may include forming a patterned mask that exposes a portion of the ILD1 layer and selectively removing the exposed portion of the ILD1 layer and the underlying ILD0 layer to form the opening. In various embodiments, the patterned mask may include a photo resist layer. The patterned mask may be formed by photoresist coating (e.g., spin-on coating), soft baking, mask aligning, exposure, post-exposure baking, developing the photoresist, rinsing, drying (e.g., hard baking), and/or combinations thereof. In some other embodiments, various imaging enhancement layers may be formed under photo resist layer to enhance the pattern transfer. The imaging enhancement layer may comprise a tri-layer including a bottom organic layer, a middle inorganic layer and a top organic layer. The imaging enhancement layer may also include an anti-reflective coating (ARC) material, a polymer layer, an oxide derived from TEOS (tetraethylorthosilicate), silicon oxide, or a Si-containing anti-reflective coating (ARC) material, such as a 42% Si-containing ARC layer. In yet some other embodiments, the patterned mask layer includes a hard mask layer. The hard mask layer includes an oxide material, silicon nitride, silicon oxynitride, an amorphous carbon material, silicon carbide or tetraethylorthosilicate (TEOS).

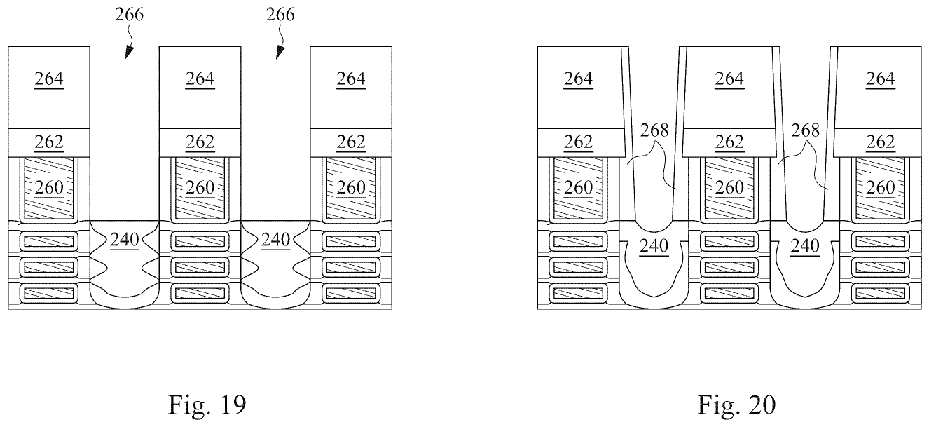

Referring to the example of FIG. 19, in an embodiment of block 136, the example semiconductor structure includes an opening 266 in the ILD1 layer 264 and the ILD0 layer 244 that expose the underlying source/drain features 240. The ILD1 layer 264 and ILD0 layer 244 are selectively removed to create the opening 266 to expose the S/D features 240. The exposed portions of the ILD1 layer 264 and ILD0 layer 244 can be removed by suitable etching process, such as wet etching, dry etching, or combination thereof. The dielectric layer 262 protects the gate structure 260 during etching operations to expose the S/D features 240.

At block 138, the example method 100 includes forming a dielectric liner in the opening that exposes the S/D regions. The dielectric liner may be formed from a material such as SiN and may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. Referring to the example of FIG. 20, in an embodiment of block 138, the example semiconductor structure includes a dielectric liner 268 formed on sidewalls of the opening 266.

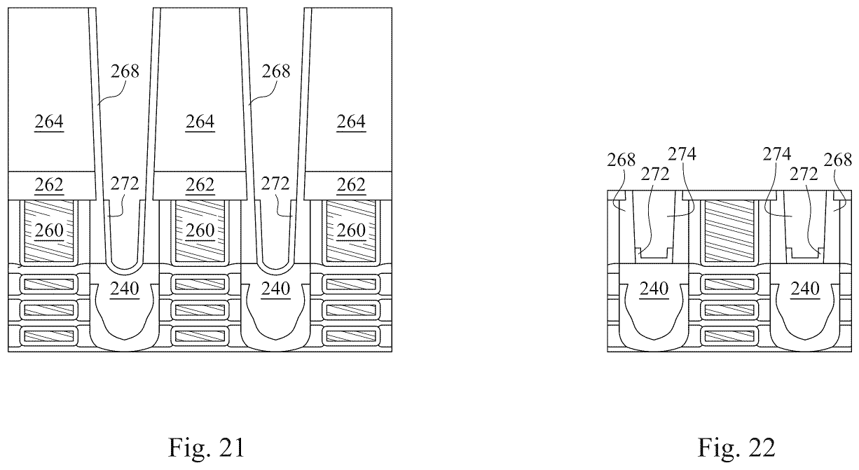

At block 140, the example method 100 includes forming silicide contacts on the source/drain regions. Because the S/D features for n-type FETs may comprise SiP, the S/D features for p-type FETs may comprise SiGe, and the dielectric liner 268 may comprise SiN, Silicide contacts can be formed contacting the Si of the dielectric liner 268 and the S/D features 240. The silicide contact may comprise titanium (e.g., titanium silicide (TiSi)) in order to reduce the Schottky barrier height of the contact. However, other metals, such as nickel (e.g., nickel silicide (NiSi)), cobalt (e.g., cobalt silicide (CoSi)), copper (e.g., copper silicide (CuSi)), and others, may also be used. A silicidation may be performed by blanket deposition of an appropriate metal layer, followed by an annealing step which causes the metal to react with the underlying exposed silicon of the source/drain regions and silicon of the dielectric liner. Referring to the example of FIG. 21, in an embodiment after completion of block 140, the semiconductor structure includes silicide contacts 272 on the S/D features 240 and a portion of the dielectric liner 268.

At block 142, the example method 100 includes filling a conductive material in the openings contacting the silicide in the source/drain regions to form source/drain contacts (also referred to herein as metal drain (MD) contacts). The source/drain contact may comprise one or more layers. For example, in some embodiments, the source/drain contact comprise a liner and a metal fill material (not individually shown) deposited by, for example, CVD, ALD, electroless deposition (ELD), PVD, electroplating, or another deposition technique. The liner, such as a diffusion barrier layer, an adhesion layer, or the like, may include titanium, titanium nitride, tantalum, tantalum nitride, or the like. The conductive material may be copper, a copper alloy, silver, gold, tungsten, cobalt, aluminum, ruthenium, nickel, or the like. A planarization process, such as a CMP, may be performed to remove excess liner and conductive material. The remaining liner and conductive material form the source/drain contact in the opening. Referring to the example of FIG. 22, in an embodiment after completion of block 142, the semiconductor structure includes a conductive material in the openings 266 (shown in FIG. 22) and contacting the source/drain features 240 through the silicide contacts 272 to form source/drain contacts (MD 274).

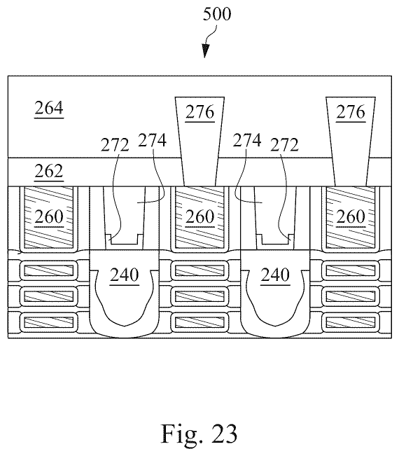

At block 144, the example method 100 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal (such as VG 276 illustrated in FIG. 23), as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

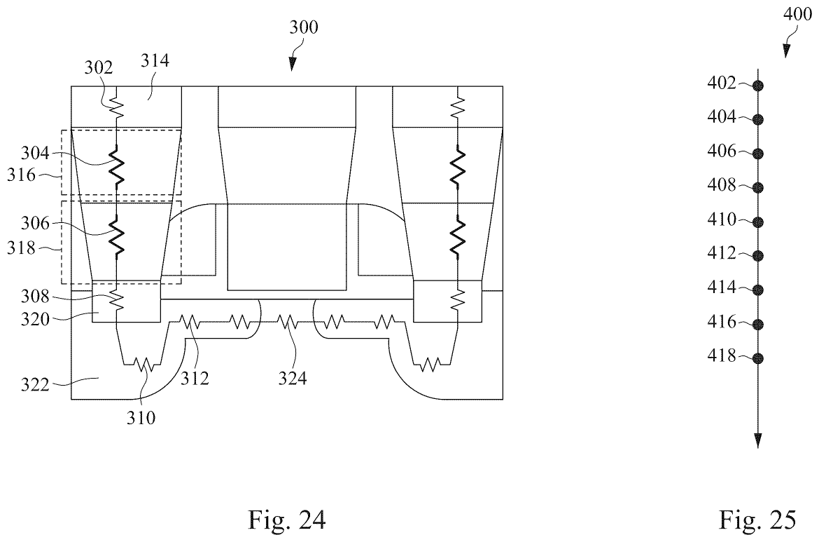

FIG. 24 is a schematic diagram illustrating an example contact loop 300 in a transistor device. The contact loop models the resistance between BEOL (back-end-of-line) components 314 (e.g., metal lines and vias), source/drain contacts (VD plug 316), source/drain terminal (MD plug 318), silicide 320, source/drain feature 322, and channel region 324. In various embodiments, a loop resistance (Rp) can be expressed as follows:

Rₚ=R_{ldd}(312)+R_{sd}(310)+R_{csd}(308)+R_{MD-plug}(306)+R_{VD-plug}(304)+R_{BEOL}(302).

The resistance represents the difficulty of a current passing through a conductor. The use of lower resistivity metal for a conductor or providing a larger critical dimension at interfaces between components can lower the loop resistance. When fabricating different layers, certain processes such as dry etching can often leave byproducts in the metal used for conductors that can induce resistance degradation (i.e., increased resistance). The shrinking transistor dimensions also causes an increase in contact resistance. Structures and techniques disclosed herein can provide reduced contact resistance by increasing contact area, which reduces contact resistance, and by enhancing metal interface cleanliness, which reduces byproducts in the metal used for conductors and guard against resistance degradation.

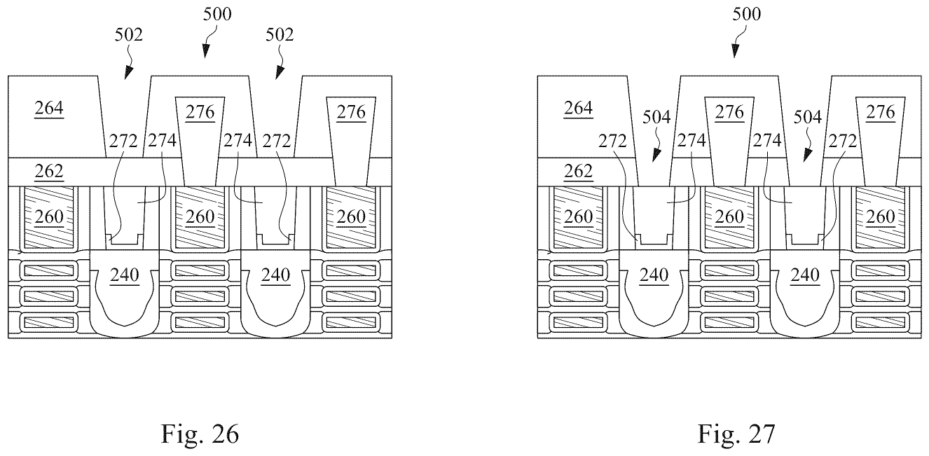

FIG. 25 is a flow diagram depicting an example method 400 for forming a source/drain contact (e.g., VD plug 316) with lower resistance, according to various aspects of the present disclosure. FIG. 25 is described in conjunction with FIGS. 26-29, which illustrate a semiconductor structure 500 or structure at various stages of fabrication in accordance with some embodiments. The method 400 is merely an example and is not intended to limit the present disclosure beyond what is explicitly recited in the claims. Additional steps may be provided before, during, and after method 400, and some of the steps described can be moved, replaced, or eliminated for additional embodiments of method 400. Additional features may be added in the semiconductor structure 500 depicted in the figures, and some of the features described below can be replaced, modified, or eliminated in other embodiments.

At 402, the example method 400 includes forming a first patterned mask over the semiconductor structure 500 in an area where a source drain contact is to be formed. The semiconductor structure 500 includes a gate structure 260, source/drain features 240 on opposite sides of the gate structure 260, silicide contacts 272 formed above the source/drain features 240, a MD 274 formed above the silicide contacts 272, an ILD0 dielectric layer 262 formed above the gate structure 260 and MD 274, an ILD1 dielectric layer 264 formed above the ILD0 dielectric layer 262, and a VG 276 formed above the gate structure 260 in the ILD0 dielectric layer 262 and the ILD1 dielectric layer 264. FIG. 23 illustrates a schematic cross sectional view of the example semiconductor structure 500.

The first patterned mask may be formed by a photolithography process. The photolithography process may include forming a photoresist layer over the ILD1 dielectric layer 264, exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the ILD1 dielectric layer 264, while an etch process forms trenches in unprotected regions through masking layer(s) such as hard mask. The trenches may be etched using a dry etch (e.g., reactive ion etching), a wet etch, and/or other suitable processes.

At 404, the example method 400 includes forming a first trench in the ILD1 dielectric layer in the area where a source drain contact is to be formed. The ILD1 dielectric layer can be removed to form the first trench in the area where a source drain contact is to be formed by suitable etching process, such as wet etching, dry etching, or combination thereof.

At 406, the example method 400 includes performing a wet clean process to remove the first patterned mask using a suitable technique. Referring to the example of FIG. 26, in an embodiment after completion of 402, 404, and 406, the semiconductor structure 500 at this stage of fabrication includes a first trench 502 that extends through the ILD1 dielectric layer 264 to the top of the ILD0 dielectric layer 262.

At 408, the example method 400 includes forming a second patterned mask over the semiconductor structure 500 in an area where the source drain contact is to be formed. The second patterned mask may be formed by a photolithography process. The photolithography process may include forming a photoresist layer over the ILD1 dielectric layer 264, exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the ILD1 dielectric layer 264, while an etch process forms trenches in unprotected regions through masking layer(s) such as hard mask. The trenches may be etched using a dry etch (e.g., reactive ion etching), a wet etch, and/or other suitable processes.

At 410, the example method 400 includes forming a second trench that extends in the ILD0 dielectric layer in the area where a source drain contact is to be formed. The ILD0 dielectric layer can be removed to form the second trench in the area where a source drain contact is to be formed by suitable etching process, such as wet etching, dry etching, or combination thereof.

At 412, the example method 400 includes performing a wet clean process to remove the second patterned mask. At 414, the example method 400 includes a sidewall passivation treatment to the sidewall of the first trench 502 and the sidewall of the second trench 504.

Referring to the example of FIG. 27, in an embodiment after completion of 408, 410, 412, and 414, the semiconductor structure 500 at this stage of fabrication includes a second trench 504 that extends through the ILD0 dielectric layer 262 to the top of the MD 274.

At 416, the example method 400 includes forming an MD recess in the source/drain terminal (MD). In various embodiments, the MD recess has concave-shaped top surface. The recess provides a larger surface area for connecting a drain contact (VD) to the source/drain terminal (MD). The larger surface area can reduce resistance and thereby improve device performance. In sor

$$Resistance : {R}_{↓} = ρ \times \frac{L}{A ↑}$$

wherein resistance decreases as the surface area at a connection location increases. The recess profile facilitates the increase of the contact area between the drain contact (VD) and the source/drain terminal (MD).

In various embodiments, the MD recess may be formed in the source/drain terminal (MD) via a plasma etching process using one or more of H₂/O₂/CF₄/C₄F₆/C₄F₈/HBr/O₂/Cl₂/BCl₃/N₂ and a wet clean process using a chelating agent, such as HCl, or an oxidant agent such as H₂O₂ or DIO₃. If DIO₃ is used, the concentration may range from 200 ppm to 6 ppm. In various embodiments, this concentration of DIO₃ can effectively control the etch rate (ER) of MD metal.

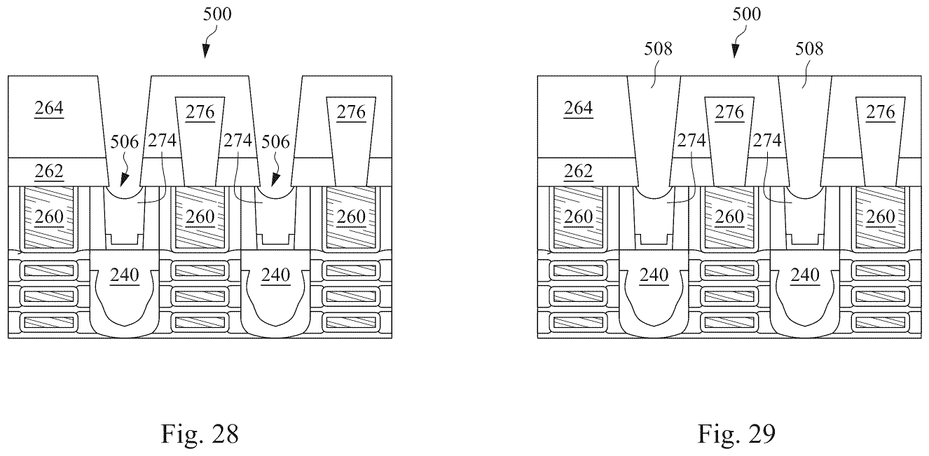

Referring to the example of FIG. 28, in an embodiment after completion of 416, an MD recess 506 is formed in the MD 274. The MD recess 506 has a concave-shaped top surface. The MD recess 506 is wider than the width in the second trench 504 and extends below the ILD0 layer 262.

At 418, the example method 400 includes forming a drain contact (VD) in the MD recess, second trench, and first trench. In various embodiments, the drain contact (VD) has a convex-shaped bottom surface. The drain contact (VD) may be formed via a suitable etching technique.

Referring to the example of FIG. 29, in an embodiment after completion of 418, a drain contact (VD 508) is formed in the MD recess 506, second trench 504, and first trench 502. The example drain contact (VD 508) has a convex-shaped bottom surface. The VD 508 may be formed from a low resistivity metal, such as Co, W, Mo, Ru, and others. The drain contact (VD) may be formed with a thickness from about 10 nm to about 30 nm.

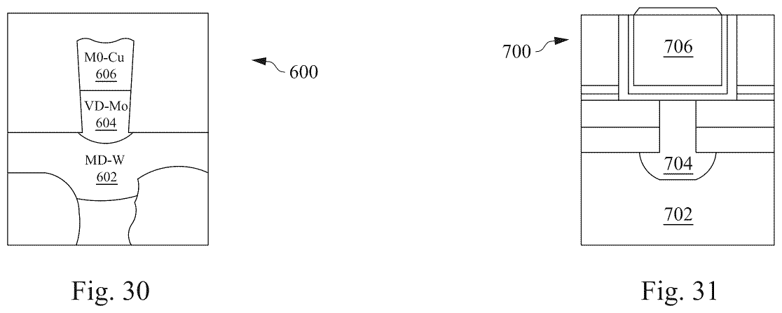

FIG. 30 depicts a cross-sectional view of an example semiconductor structure 600. The example semiconductor structure 600 includes a source/drain terminal 602 made from tungsten, a source/drain contact 604 connected to the source/drain terminal 602, and a MO BEOL interconnect structure 606 (e.g., VIA) made from copper connected to the source/drain contact 604.

FIG. 31 depicts a schematic cross-sectional view of an example semiconductor structure 700. The semiconductor structure 700 includes a source/drain terminal 702, a source/drain contact 704 connected to the source/drain terminal 702, and a MO BEOL interconnect structure 706 (e.g., VIA) connected to the source/drain contact 704.

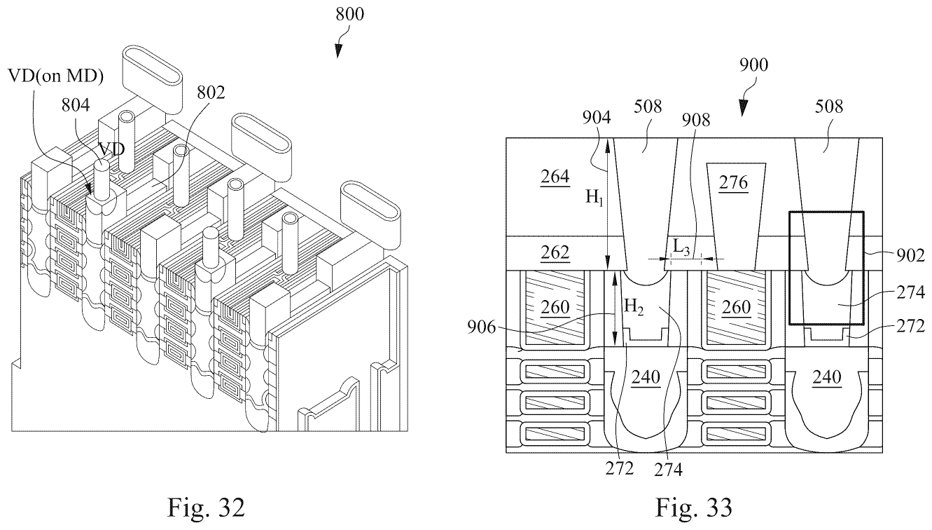

FIG. 32 depicts a perspective view of an example semiconductor structure 800. The semiconductor structure 800 includes a source/drain terminal 802 and a source/drain contact 804 connected to the source/drain terminal 802.

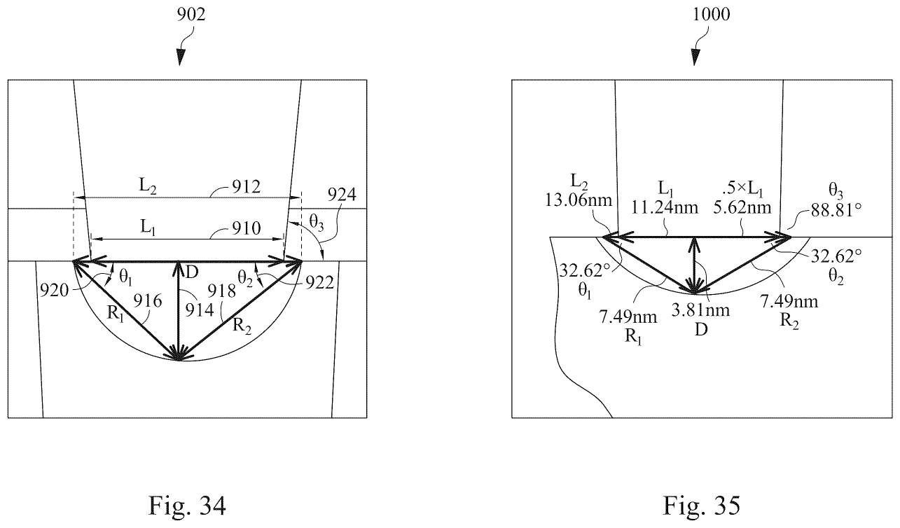

FIG. 33 depicts a schematic cross-sectional view of an example semiconductor structure 900. FIG. 34 depicts a schematic cross-sectional view of section 902 of the example semiconductor structure 900 of FIG. 33.

The semiconductor structure 900 includes a gate structure 260, source/drain features 240 on opposite sides of the gate structure 260, silicide contacts 272 formed above the source/drain features 240, a MD 274 formed above the silicide contacts 272, an ILD0 dielectric layer 262 formed above the gate structure 260 and MD 274, an ILD1 dielectric layer 264 formed above the ILD0 dielectric layer 262, a VG 276 formed above the gate structure 260 in the ILD0 dielectric layer 262 and the ILD1 dielectric layer 264, and a VD 508 formed above the MD 274.

As illustrated in FIG. 33, in the example semiconductor structure 900, the VD 508 has a height 904 (H₁), the MD 274 has a height 906 (H₂), and the semiconductor structure 900 has a VD-to-MG distance 908 (L₃). As illustrated in FIG. 34, in the example semiconductor structure 900, the VD 508 has a VIA opening length 910 (L₁) between ends of the trench in the dielectric layer 262, contact area length 912 (L₂) underneath the dielectric layer 262, recess depth 914 (D), a first distance 916 between one end of the trench to a center point at a bottom of the recess (R₁), a second distance 918 second distance between a second end of the trench to the center point (R₂), a first interior angle 920 (θ₁) defined between a first line segment between one end of the concave top surface to a bottom center of the source/drain contact and a line segment across the top of the source/drain contact, a second interior angle 922 (θ₂) defined between a second line segment between an opposite end of the concave top surface to the bottom center of the source/drain contact and the line segment across the top of the source/drain contact, and an exterior angle 924 (θ₃) defined between a sidewall of the source/drain contact and a bottom surface of the dielectric layer.

Described below are example physical characteristics of the semiconductor structure 900. The described physical characteristics can allow the semiconductor structure 900 to have reduced resistance and improved device performance.

In various embodiments, the recess profile is symmetrical because the recess depth can act as a perpendicular bisector.

In various embodiments, the Via opening CD (L₁) range is between about 11 nm and about 15 nm. In various embodiments, 11 nm L₁ 15 nm.

In various embodiments, the lateral etching will enlarge the contact area CD (L₂) such that a difference between the second length (L₂) and the first length (L₁) is up to 3 nm. In various embodiments, 0 nm<L₂−L₁ 3 nm.

In various embodiments, the deeper recess depth will pass through the center of opening CD and the depths of D≥2 nm.

In various embodiments, the first distance between one end of the trench to a center point at a bottom of the recess and the second distance between a second end of the trench to the center point (R1 & R2) are similar. In various embodiments, the difference between the first distance and the second distance is less than 1 nm (i.e., Bias (R1-R2)<1 nm). Controlling the trench to the center point (R1-R2<1 nm) allows the recess profile to be extremely uniform, which can help avoid damaging the bottom MD silicide. This can become increasingly important, especially as future processes continue to shrink and the MD becomes shorter.

In various embodiments, the interior angles (θ₁ and θ₂) are similar. In various embodiments, the Bias (θ₁-θ₂)<10°. In various embodiments, the magnitude of the range of the interior angles (θ₁ and θ₂) is between about 15° and about 45°. In various embodiments, 15°<θ₁<45° and 15°<θ₂<45°.

In various embodiments, the range of exterior angle (θ₃) is between about 90° and about 70°. In various embodiments, 90°<θ₃<70°.

In various embodiments, the source/drain contact has a depth (D) below the dielectric layer and the source/drain contact has an effective aspect ratio (D/L₂) that is between about 0.17 and about 0.3. In various embodiments, 0.17≤D/L₂≤0.3. This range can be achieved based on an advanced manufacturing process such as one consistent with the operations described herein.

In various embodiments, the VD height ratio (H₁+D/H₁) is between about 0.15 and about 1.5. In various embodiments, 0.15≤H₁+D/H₁≤1.5.

In various embodiments, the VD Height (H₁) range is between about 14 nm and about 30 nm. In various embodiments, 14 nm≤H₁≤30 nm.

In various embodiments, the MD Height (H₂) range is between about 10 nm and about 16 nm. In various embodiments, 10 nm≤H₂≤16 nm.

In various embodiments, the VD to MG distance (L₃) range is between about 5 nm and about 15 nm. In various embodiments, 5≤nm L₃≤15 nm.

FIG. 35 depicts a cross-sectional view of an example semiconductor structure 1000. The example semiconductor includes structures with the following physical dimensions:
a VIA opening length (L₁) in a range between about 11 nm and about 15 nm—this range can be achieved based on an advanced manufacturing process such as one consistent with the operations described herein;
a contact area CD (L2) minus Via opening CD (L1) in the range of 0 nm<L2−L1≤3 nm—this range can be determined by the lateral effect of wet chemicals;
a recess depth (D) in a range of greater than or equal 2 nm—a recess depth (D) of greater than or equal to 2 nm can ensure that impurities in the process are effectively removed, resulting in better resistance performance, and can also aid in the subsequent growth of metal;
a Bias of a first distance between one end of the trench to a center point at a bottom of the recess (R₁) minus a second distance between a second end of the trench to the center point (R₂) is in the range of (R₁-R₂)<1 nm—controlling the trench to the center point (R1-R2<1 nm) can allow the recess profile to be extremely uniform, which can help avoid damaging the bottom MD silicide, which can become increasingly important, especially as future processes continue to shrink and the MD becomes shorter;
a first interior angle (θ₁) having a magnitude similar to the magnitude of a second interior angle (θ₂) with 15°<θ₁<45° and 15°<θ₂<45° wherein the Bias (θ₁-θ₂)<10°—the interior angles and Bias in these ranges can allow a uniform recess profile, approaching an even bowl shape; and
an exterior angle (θ₃) having a range between about 90° and about 70°—this range can be achieved based on an advanced manufacturing process such as one consistent with the operations described herein.

In the examples described above, novel techniques and structures for connecting a source/drain feature to a source/drain contact were provided. In the preceding examples, the source/drain contact was in the MO metallization layer. In other examples, the source/drain contact may be provided in a backside of the semiconductor structure. In these examples, the novel techniques and structures described herein also apply.

In some aspects, the techniques described herein relate to a method, including: forming a trench in a dielectric layer above a source/drain terminal of a semiconductor structure; forming a recess in a top surface of a source/drain terminal that extends below the dielectric layer; forming a source/drain contact in the trench and recess; wherein the source/drain contact has a first length between ends of the trench; and wherein the source/drain contact has a second length underneath the dielectric layer; wherein the second length is greater in magnitude than the first length.

In some aspects, the techniques described herein relate to a method, wherein the recess has a symmetrical profile.

In some aspects, the techniques described herein relate to a method, wherein a difference between the second length and the first length is up to 3 nm.

In some aspects, the techniques described herein relate to a method, wherein the recess has a depth that is deeper through a center of the recess.

In some aspects, the techniques described herein relate to a method, wherein the depth is greater than or equal to 2 nm.

In some aspects, the techniques described herein relate to a method, wherein the recess has a first distance between one end of the trench to a center point at a bottom of the recess, a second distance between a second end of the trench to the center point, a difference between the first distance and the second distance is less than 1 nm.

In some aspects, the techniques described herein relate to a method, wherein the first length is between about 11 nm and about 15 nm.

In some aspects, the techniques described herein relate to a semiconductor device, including: a gate structure around a plurality of nanosheets; a source/drain (S/D) feature adjacent to the plurality of nanosheets; a dielectric layer between the gate structure and the S/D feature; a source/drain terminal with a concave-shaped top surface disposed above the S/D feature; and a source/drain contact disposed above the source/drain terminal, the source/drain contact having a convex-shaped bottom surface that contacts the concave-shaped top surface; wherein the convex-shaped bottom surface has dimensions on different sides that are approximately symmetrical.

In some aspects, the techniques described herein relate to a semiconductor device, wherein the source/drain contact has a first distance between one end of the concave-shaped top surface to a bottom center of the source/drain contact, the source/drain contact has a second distance between an opposite end of the concave-shaped top surface to the bottom center of the source/drain contact, and the difference between the first distance and the second distance is less than 1 nm.

In some aspects, the techniques described herein relate to a semiconductor device, wherein: the source/drain contact has a first angle defined between a first line segment between one end of the concave-shaped top surface to a bottom center of the source/drain contact and a line segment across the top of the source/drain contact; the source/drain contact has a second angle defined between a second line segment between an opposite end of the concave-shaped top surface to the bottom center of the source/drain contact and the line segment across the top of the source/drain contact; and a difference between the first angle and the second angle is less than 10 degrees.

In some aspects, the techniques described herein relate to a semiconductor device, wherein a magnitude of the first angle is between about 15° and about 45° and a magnitude of the second angle is between about 15° and about 45°.

In some aspects, the techniques described herein relate to a semiconductor device, wherein: the source/drain contact has a depth below the dielectric layer; and the source/drain contact has an effective aspect ratio of depth over second length of between about 0.17 and about 0.3.

In some aspects, the techniques described herein relate to a semiconductor device, wherein: the source/drain contact has a depth below the dielectric layer; the source/drain contact has a first height above a top of the source/drain terminal; and the source/drain contact has a height ratio of first height plus the depth over the first height between about 0.15 and about 1.5.

In some aspects, the techniques described herein relate to a semiconductor device, wherein: the source/drain contact has a first height above a top of the source/drain terminal between about 14 nm and about 30 nm; and the source/drain terminal has a second height between the dielectric layer and the S/D feature that is between about 10 nm and about 16 nm.

In some aspects, the techniques described herein relate to a semiconductor device, wherein: the source/drain contact has a first length between ends across the dielectric layer; the source/drain contact has a second length underneath the dielectric layer; and the second length is greater in magnitude than the first length.

In some aspects, the techniques described herein relate to a semiconductor device, wherein: the source/drain contact has an exterior angle defined between a sidewall of the source/drain contact and a bottom surface of the dielectric layer; and a magnitude of the exterior angle is between about 90° and about 70°.

In some aspects, the techniques described herein relate to a method, including: forming a trench in a dielectric layer above a source/drain terminal of a semiconductor structure; etching a concave-shaped recess in a top surface of a source/drain terminal that extends below the dielectric layer using plasma etching; cleaning the recess using a chelating agent or a oxidant agent; forming a source/drain contact with a convex-shaped bottom surface in the trench and recess; wherein the source/drain contact has a first length between ends of the trench; and wherein the source/drain contact has a second length underneath the dielectric layer; wherein the second length is greater in magnitude than the first length.

In some aspects, the techniques described herein relate to a method, wherein cleaning the recess includes cleaning the recess using DIO₃ in a concentration range from 200 ppm to 6 ppm.

In some aspects, the techniques described herein relate to a method, wherein a difference between the second length and the first length is up to 3 nm.

In some aspects, the techniques described herein relate to a method, wherein the recess has a depth that is deeper through a center of the recess and wherein the depth is greater than or equal to 2 nm.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
forming a trench in a dielectric layer above a source/drain terminal of a semiconductor structure;
forming a recess in a top surface of a source/drain terminal that extends below the dielectric layer;
forming a source/drain contact in the trench and recess;
wherein the source/drain contact has a first length between ends of the trench; and
wherein the source/drain contact has a second length underneath the dielectric layer;
wherein the second length is greater in magnitude than the first length.

2. The method of claim 1, wherein the recess has a symmetrical profile.

3. The method of claim 1, wherein a difference between the second length and the first length is up to 3 nm.

4. The method of claim 1, wherein the recess has a depth that is deeper through a center of the recess.

5. The method of claim 4, wherein the depth is greater than or equal to 2 nm.

6. The method of claim 1, wherein the recess has a first distance between one end of the trench to a center point at a bottom of the recess, a second distance between a second end of the trench to the center point, a difference between the first distance and the second distance is less than 1 nm.

7. The method of claim 1, wherein the first length is between about 11 nm and about 15 nm.

8. A semiconductor device, comprising:
a gate structure around a plurality of nanosheets;
a source/drain (S/D) feature adjacent to the plurality of nanosheets;
a dielectric layer between the gate structure and the S/D feature;
a source/drain terminal with a concave-shaped top surface disposed above the S/D feature; and
a source/drain contact disposed above the source/drain terminal, the source/drain contact having a convex-shaped bottom surface that contacts the concave-shaped top surface;
wherein the convex-shaped bottom surface has dimensions on different sides that are approximately symmetrical.

9. The semiconductor device of claim 8, wherein the source/drain contact has a first distance between one end of the concave-shaped top surface to a bottom center of the source/drain contact, the source/drain contact has a second distance between an opposite end of the concave-shaped top surface to the bottom center of the source/drain contact, and the difference between the first distance and the second distance is less than 1 nm.

10. The semiconductor device of claim 8, wherein:
the source/drain contact has a first angle defined between a first line segment between one end of the concave-shaped top surface to a bottom center of the source/drain contact and a line segment across the top of the source/drain contact;
the source/drain contact has a second angle defined between a second line segment between an opposite end of the concave-shaped top surface to the bottom center of the source/drain contact and the line segment across the top of the source/drain contact; and
a difference between the first angle and the second angle is less than 10 degrees.

11. The semiconductor device of claim 10, wherein a magnitude of the first angle is between about 15° and about 45° and a magnitude of the second angle is between about 15° and about 45°.

12. The semiconductor device of claim 8, wherein:
the source/drain contact has a depth below the dielectric layer; and
the source/drain contact has an effective aspect ratio of depth over second length of between about 0.17 and about 0.3.

13. The semiconductor device of claim 8, wherein:
the source/drain contact has a depth below the dielectric layer;
the source/drain contact has a first height above a top of the source/drain terminal; and
the source/drain contact has a height ratio of first height plus the depth over the first height between about 0.15 and about 1.5.

14. The semiconductor device of claim 8, wherein:
the source/drain contact has a first height above a top of the source/drain terminal between about 14 nm and about 30 nm; and
the source/drain terminal has a second height between the dielectric layer and the S/D feature that is between about 10 nm and about 16 nm.

15. The semiconductor device of claim 8, wherein:
the source/drain contact has a first length between ends across the dielectric layer;
the source/drain contact has a second length underneath the dielectric layer; and
the second length is greater in magnitude than the first length.

16. The semiconductor device of claim 8, wherein:
the source/drain contact has an exterior angle defined between a sidewall of the source/drain contact and a bottom surface of the dielectric layer; and
a magnitude of the exterior angle is between about 90° and about 70°.

17. A method, comprising:
forming a trench in a dielectric layer above a source/drain terminal of a semiconductor structure;
etching a concave-shaped recess in a top surface of the source/drain terminal that extends below the dielectric layer using plasma etching;
cleaning the recess using a chelating agent or an oxidant agent;
forming a source/drain contact with a convex-shaped bottom surface in the trench and recess;
wherein the source/drain contact has a first length between ends of the trench; and
wherein the source/drain contact has a second length underneath the dielectric layer;
wherein the second length is greater in magnitude than the first length.

18. The method of claim 17, wherein cleaning the recess comprises cleaning the recess using DIO₃ in a concentration range from 200 ppm to 6 ppm.

19. The method of claim 17, wherein a difference between the second length and the first length is up to 3 nm.

20. The method of claim 17, wherein the recess has a depth that is deeper through a center of the recess and wherein the depth is greater than or equal to 2 nm.
